(19) United States
(12) Patent Application Publication
(10) Pub. No.: US 2006/0267689 A1
(43) Pub. Date: Nov. 30, 2006

(54) Parallel power amplifier apparatus, method, and system

(75) Inventors: Mostafa Elmala, Tigard, OR (US); Stewart S. Taylor, Beaverton, OR (US)

Correspondence Address: LeMoine Patent Services, PLLC;C/O PortfolioIP, P.O. Box 52050, Minneapolis, MN, 55402, US

(73) Assignee: Intel Corporation

(21) Appl. No.: 11/135,884

(22) Filed: May 24, 2005

(51) Int. Cl. H03F 3/68

(52) U.S. Cl. 330/295

(57) ABSTRACT

Parallel coupled amplifiers are biased to reduce amplitude to phase distortion with increasing input power.

### FIELD

The present invention relates generally to amplifier circuits, and more specifically to parallel amplifier circuits.

### BACKGROUND

Amplifiers coupled in parallel may provide a large output power by combining output power from each of the parallel coupled amplifiers to form a single output signal. Large signal fluctuations in parallel coupled amplifiers may result in amplitude modulation (AM) to phase modulation (PM) distortion.

### BRIEF DESCRIPTION OF THE DRAWINGS

FIG. 1 shows a diagram of a parallel power amplifier circuit;

FIG. 2 shows a schematic of an amplifier circuit;

FIG. 3 shows a diagram of gate-to-source capacitance as a function of gate-to-source voltage;

FIGS. 4 and 5 show diagrams of phase variation with increasing input power;

FIG. 6 shows a diagram of a parallel power amplifier circuit;

FIG. 7 shows a diagram of gate-to-source capacitance as a function of gate-to-source voltage;

FIG. 8 shows a diagram of an electronic system in accordance with various embodiments of the present invention; and

FIG. 9 shows a flowchart in accordance with various embodiments of the present invention.

### DESCRIPTION OF THE EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

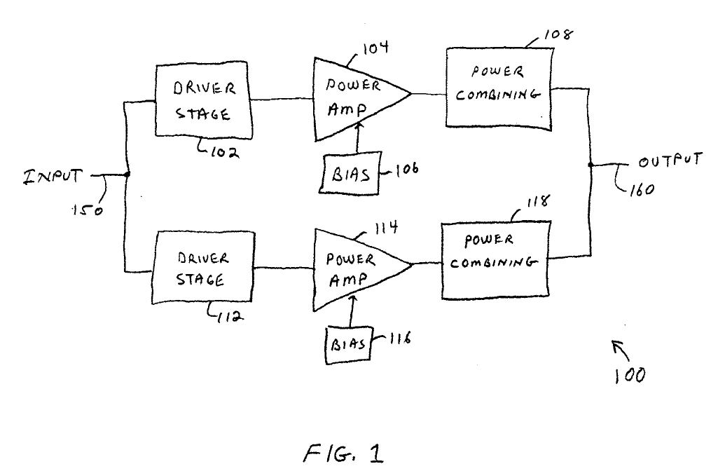

FIG. 1 shows a diagram of a parallel power amplifier circuit. Parallel power amplifier circuit 100 includes amplifiers 104 and 114, bias circuits 106 and 116, driver stages 102 and 112, and power combining circuits 108 and 118. Parallel amplifier circuit 100 is shown having two parallel amplifier paths. A first path is formed by driver stage 102, power amplifier 104, and power combining circuit 108; and a second path is formed by driver stage 112, power amplifier 114, and power combining circuit 118.

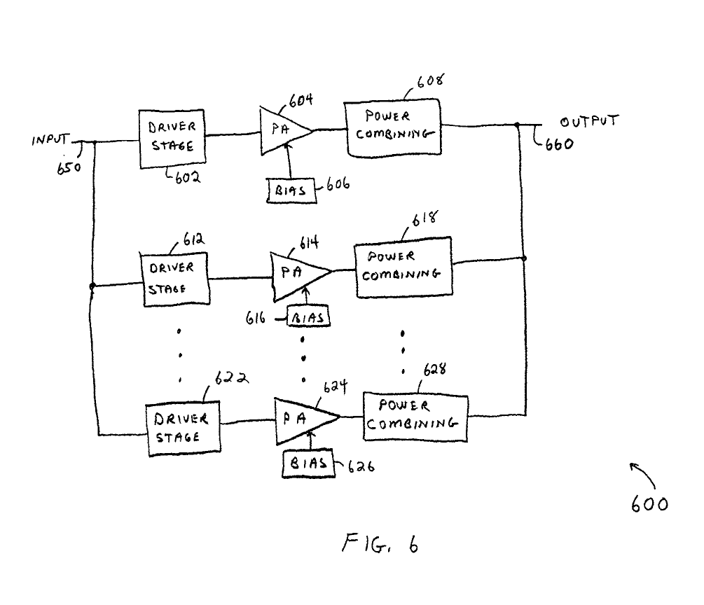

Parallel power amplifier circuit 100 is shown in FIG. 1 having two parallel paths, although this is not a limitation of the present invention. For example, in some embodiments, parallel power amplifier circuit 100 includes more than two parallel paths. An example parallel power amplifier with more than two paths is described below with reference to FIG. 6.

In operation, an input signal is received on node 150, and the input signal is distributed to each parallel path. The driver stage in each path receives the input signal, and prepares the input signal for power amplification by the power amplifier in the path. The power amplifier in each path amplifies the signal, and the power combining circuits deliver the resultant combined output signal on node 160.

Parallel power amplifier circuit 100 may be utilized in different types of architectures to achieve various results. For example, parallel power amplifier circuit 100 can provide larger maximum output power by combining the power from the power amplifiers in the various paths. Also for example, parallel power amplifier circuit 100 may provide high efficiency across a wide input power variation by selecting various operating points for the various power amplifiers.

Various embodiments of the present invention reduce amplitude-to-phase (AM-to-PM) distortion in parallel power amplifiers by selecting appropriate bias points for the various parallel amplifiers. For example, as shown in FIG. 1, bias circuits 106 and 116 can separately bias power amplifiers 104 and 114, respectively. As described further below, a bias point for a first power amplifier can be chosen so that the power amplifier has a phase characteristic that changes in a first direction with increasing input power, and a bias point for a second power amplifier can be chosen so that the power amplifier has a phase characteristic that changes in a direction opposite the first direction with increasing input power. When output power from both power amplifiers is combined, the phase characteristics combine to reduce phase variation with increasing input power.

In some embodiments, the various amplifiers are biased to operate in different classes. For example, power amplifier 104 may be biased to operate as a class C amplifier, and power amplifier 114 may be biased to operate as a class A amplifier. Also for example, in some embodiments of the present invention, parallel power amplifier circuit 100 may operate with two power amplifiers as a “Doherty” power amplifier. Doherty amplifiers are known amplifiers that may include multiple power amplifiers operating in different classes to achieve high efficiency across the upper range of output power. Bias points in a Doherty power amplifier may be chosen to reduce the AM-PM distortion.

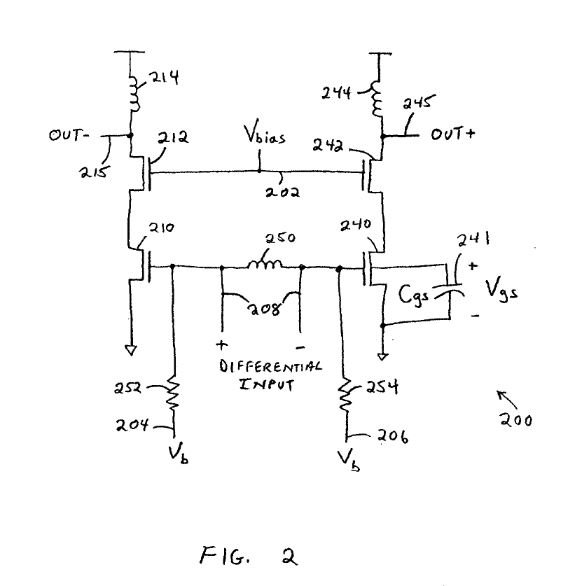

FIG. 2 shows a schematic of an amplifier circuit. Amplifier circuit 200 represents an amplifier that may be utilized for one or more of power amplifiers 104, 114, or 124 (FIG. 1). Amplifier circuit 200 includes amplifying transistors 210 and 240, cascode transistors 212 and 242, inductors 214, 244, and 250, and resistors 252 and 254.

In operation, amplifying transistors 210 and 240 are biased by bias voltage Vb, and cascode transistors 212 and 242 are biased by voltage Vbias. A differential input voltage is received on input nodes 208, and a differential output signal is produced on output nodes 215 and 245. Cascode transistors 212 and 242 are coupled to provide increased output impedance, and inductors 214 and 244 are coupled as load devices. Bias voltage Vbias on node 202 may be set to provide a nominal gate voltage on cascode transistors 212 and 242.

Amplifying transistors 210 and 240 receive a direct current (DC) bias voltage Vb from nodes 204 and 206. Vb may be provided by a bias circuit such as bias circuit 106 or 116 (FIG. 1). Amplifying transistors 210 and 240 have a nominal gate-to-source voltage Vgs that is determined by the bias voltage Vb. Vgs of amplifying transistors 210 and 240 varies about the nominal value as the input signal received on nodes 208 varies.

Amplifying transistors 210 and 240 exhibit a gate-to-source capacitance Cgs that varies as the gate-to-source voltage Vgs varies. This is shown modeled in FIG. 2 as capacitor 241. Capacitor 241 only models the capacitance Cgs, and is not a separate lumped element in the amplifier. As described above, Vgs varies around a voltage established by the DC bias voltage Vb, and the amount of variation is determined by the amplitude of the input signal received on node 208. Further, amplitude-to-phase (AM-PM) distortion varies as Cgs varies.

Various embodiments of the present invention select values for Vb based on a desired phase characteristic. For example, a first amplifier circuit may be biased to have a particular phase characteristic as a function of increasing input power, and a second amplifier circuit may be biased to have a different phase characteristic as a function of increasing input power. Amplifiers such as amplifier circuit 200 can be coupled in parallel together to deliver increased power through power combining as shown in FIG. 1, and the phase characteristics of the parallel coupled amplifiers may be chosen so that the total AM-PM distortion is reduced.

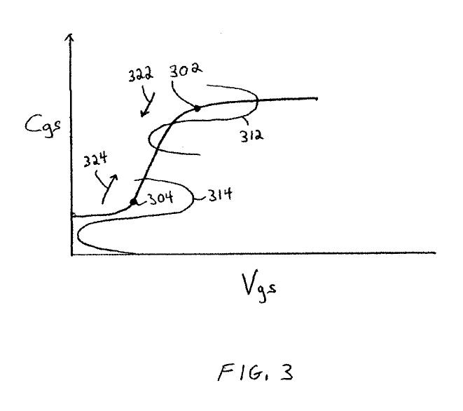

FIG. 3 shows a diagram of gate-to-source capacitance as a function of gate-to-source voltage and bias point for two amplifiers. Curve 300 shows that Cgs increases with Vgs. Superimposed on curve 300 are two points 302 and 304 that represent bias points of two parallel coupled amplifiers. For example, point 302 may represent a bias point of power amplifier 104 (FIG. 1 ), and point 304 may represent a bias point of power amplifier 114 (FIG. 1). Points 302 and 304 show nominal values for Cgs for amplifiers biased with the corresponding Vgs.

Also superimposed on curve 300 are two curves that represent input voltage swings around the bias points that result from increasing input power at the amplifier input. For example, curve 312 may represent a changing input voltage at the input of power amplifier 104 (FIG. 1), and curve 314 may represent a changing input voltage at the input of power amplifier 114 (FIG. 1). As the input power increases, the magnitude of curves 312 and 314 also increases. As the magnitude of curves 312 and 314 increases, the average capacitance may change. For example, as curve 312 becomes larger, the average capacitance decreases, and as curve 314 becomes larger, the average capacitance increases.

A change in average Cgs may or may not result from an increase in input power, depending at least in part on the bias point of the amplifier. For example, an amplifier with bias point 302 may experience a decrease in average Cgs as the input power increases. This decrease in average Cgs is represented by arrow 322. Also for example, an amplifier with bias point 304 may experience an increase in average Cgs as the input power increases. This increase in average Cgs is represented by arrow 324. FIG. 3 shows two bias points, corresponding to two parallel power amplifiers, although this is not a limitation of the present invention. For example, some embodiments include more than two parallel power amplifiers.

In some embodiments of the present invention, bias points 302 and 304 are chosen such that the average input capacitance of the parallel power amplifiers is substantially constant. For example, the bias points 302 and 304 may be chosen such that the magnitude of the average capacitance change is substantially the same in the two amplifiers, whereas the direction of the average capacitance change is opposite for the two amplifiers.

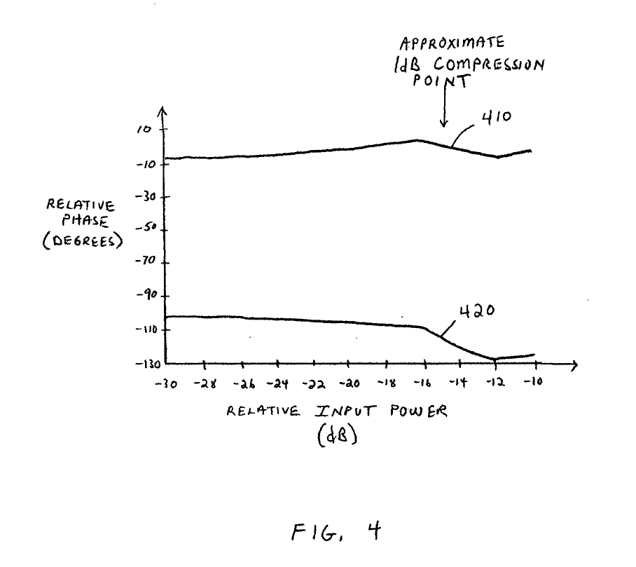

FIG. 4 shows a diagram of phase variation with increasing input power. Curve 410 shows an increasing phase, and curve 420 shows a decreasing phase. Curves 410 and 420 were produced from a simulation of an amplifier that includes two parallel power amplifiers operating in classes A/B and C. The power combiner in this simulation was a single quarter wave transmission line. The circuit implementation of each power amplifier is the amplifier circuit 200 shown in FIG. 2, where two cascode amplifiers are loaded with choke inductors. Curve 410 corresponds to a power amplifier having a bias point similar to bias point 304 (FIG. 3), and curve 420 corresponds to a power amplifier having a bias point similar to bias point 302 (FIG. 3). The amplifier represented by curve 410 exhibits a phase response that varies in one direction with increasing input power, and the amplifier represented by curve 420 exhibits a phase response that varies in the opposite direction with increasing input power. The bias points of the parallel power amplifiers were chosen to have this behavior.

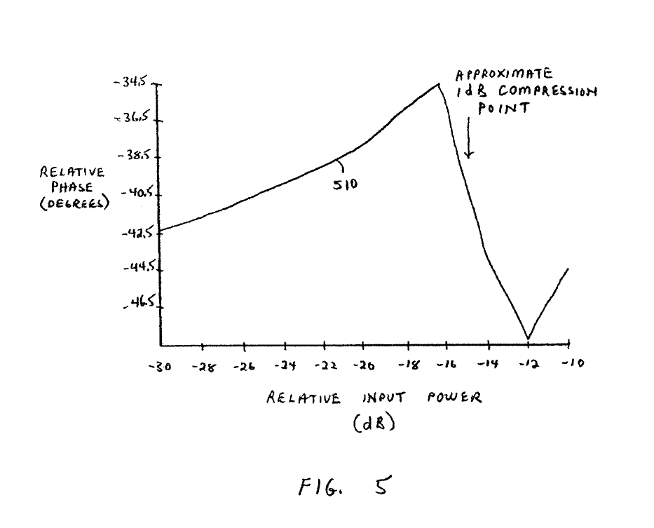

FIG. 5 shows a phase response at the output of a parallel amplifier. Curve 510 was produced in the same simulation as curves 410 and 420 (FIG. 4), and represents the overall phase variation of a parallel power amplifier. For example, curve 510 represents the phase variation at node 160 (FIG. 1) when curve 410 (FIG. 4) represents the phase response at the output of power amplifier 104 (FIG. 1) and curve 420 (FIG. 4) represents the phase response at the output of power amplifier 114 (FIG. 1). Curve 510 shows the small variation in the output phase when the input power increases.

FIG. 6 shows a diagram of a parallel power amplifier circuit. Parallel power amplifier circuit 600 includes amplifiers 604, 614, and 624, bias circuits 606, 616, and 626, driver stages 602, 612, and 622, and power combining circuits 608, 618, and 628. Parallel amplifier circuit 600 is shown having three parallel amplifier paths. A first path is formed by driver stage 602, power amplifier 604, and power combining circuit 608; a second path is formed by driver stage 612, power amplifier 614, and power combining circuit 618; and a third path is formed by driver stage 622, power amplifier 624, and power combining circuit 628.

Parallel power amplifier circuit 600 is shown in FIG. 6 having three parallel paths, although this is not a limitation of the present invention. For example, in some embodiments, parallel power amplifier circuit 600 includes four or more parallel paths.

Parallel power amplifier 600 operates similarly to parallel power amplifier 100 (FIG. 1), but with more amplifier paths in parallel. In operation, an input signal is received on node 650, and the input signal is distributed to each parallel path. The driver stage in each path receives the input signal, and prepares the input signal for power amplification by the power amplifier in the path. The power amplifier in each path amplifies the signal, and the power combining circuits drive the resultant combined output signal on node 660.

Bias points for power amplifiers 604, 614, and 624 may be chosen to reduce amplitude-to-phase (AM-to-PM) distortion in the parallel combination. For example, as shown in FIG. 6, bias circuits 606, 616, and 626 can separately bias power amplifiers 604, 614, and 624, respectively. As described above, a bias point for a first power amplifier can be chosen so that the power amplifier has a phase characteristic that changes in a first direction with increasing input power, and a bias point for a second power amplifier can be chosen so that the power amplifier has a phase characteristic that changes in a direction opposite the first direction with increasing input power. Further, a bias point for a third power amplifier can be chosen so that the power amplifier has a desired phase characteristic. The desired phase characteristic may include a positive or negative average phase change with increasing input power, or may include a relatively flat phase characteristic with increasing input power. When output power from all power amplifiers in circuit 600 is combined, the phase characteristics combine to reduce phase variation with increasing input power.

In some embodiments, the various amplifiers are biased to operate in different classes. For example, power amplifier 604 may be biased to operate as a class C amplifier, and power amplifier 614 may be biased to operate as a class A amplifier. Any number and combination of bias points or amplifier classes may be combined without departing from the scope of the present invention.

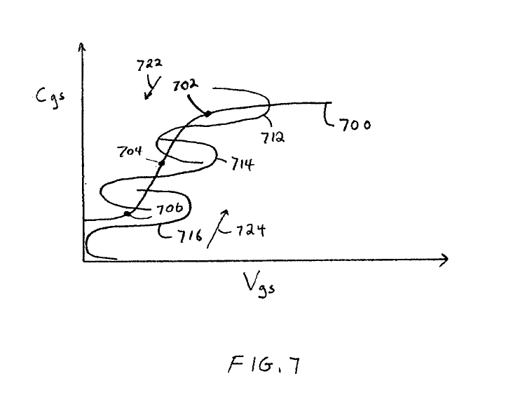

FIG. 7 shows a diagram of gate-to-source capacitance as a function of gate-to-source voltage and bias point for three amplifiers. Curve 700 shows that Cgs increases with Vgs. Superimposed on curve 700 are three points 702, 704, and 706 that represent bias points of three parallel coupled amplifiers. For example, point 702 may represent a bias point of power amplifier 604 (FIG. 6), point 704 may represent a bias point of power amplifier 614 (FIG. 6), and point 706 may represent a bias point of power amplifier 624 (FIG. 6). Points 702, 704, and 706 show nominal values for Cgs for amplifiers biased with the corresponding Vgs.

Also superimposed on curve 700 are three curves that represent input voltage swings around the bias points that result from increasing input power at the amplifier input. For example, curve 712 may represent a changing input voltage at the input of power amplifier 604 (FIG. 6), curve 714 may represent a changing input voltage at the input of power amplifier 614 (FIG. 6) and curve 716 may represent a changing input voltage at the input of power amplifier 624 (FIG. 6). As the input power increases, the magnitude of curves 712, 714, and 716 also increases. As the magnitude of curves 712, 714, and 716 increases, the average capacitance may change. For example, as curve 712 becomes larger, the average capacitance decreases, and as curve 716 becomes larger, the average capacitance increases.

A change in average Cgs may or may not result from an increase in input power, depending at least in part on the bias point of the amplifier. For example, an amplifier with bias point 702 may experience a decrease in average Cgs as the input power increases. This decrease in average Cgs is represented by arrow 722. Also for example, an amplifier with bias point 706 may experience an increase in average Cgs as the input power increases. This increase in average Cgs is represented by arrow 724. Also for example, an amplifier with bias point 704 may experience little or no change in average Cgs as the input power increases. FIG. 7 shows three bias points, corresponding to three parallel power amplifiers, although this is not a limitation of the present invention. For example, some embodiments include more than three parallel power amplifiers. Further, the bias points of the various amplifiers may be distributed along curve 700 in any fashion without departing from the scope of the present invention.

In some embodiments of the present invention, bias points 702, 704, and 706 are chosen such that the average capacitance of the parallel power amplifiers is substantially constant. For example, the bias points 702, 704, and 706 may be chosen such that the sum of the average capacitance changes for the three amplifiers results in an overall decrease in capacitance change with increasing input power.

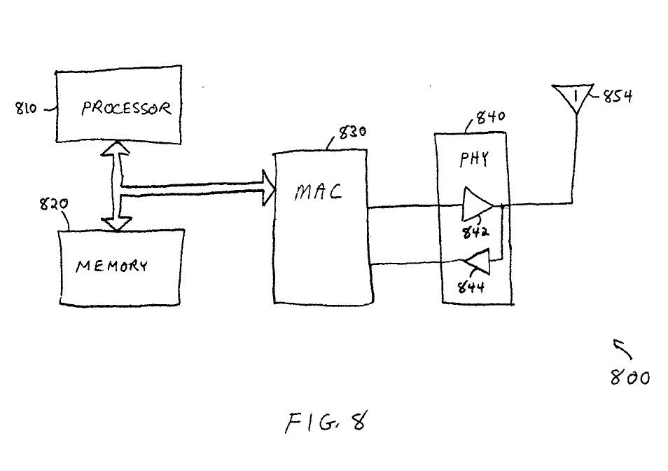

FIG. 8 shows a system diagram in accordance with various embodiments of the present invention. Electronic system 800 includes antenna 850, physical layer (PHY) 840, media access control (MAC) layer 830, processor 810, and memory 820. In operation, system 800 sends and receives signals using antenna 850, and the signals are processed by the various elements shown in FIG. 8.

Antenna 850 may include one or more antennas. For example, antenna 850 may include a single directional antenna or an omni-directional antenna. As used herein, the term omni-directional antenna refers to any antenna having a substantially uniform pattern in at least one plane. For example, in some embodiments, antenna 850 may include a single omni-directional antenna such as a dipole antenna, or a quarter wave antenna. Also for example, in some embodiments, antenna 350 may include a single directional antenna such as a parabolic dish antenna or a Yagi antenna. In still further embodiments, antenna 850 may include multiple physical antennas. For example, in some embodiments, multiple antennas are utilized for multiple-input-multiple-output (MIMO) processing or spatial-division multiple access (SDMA) processing.

Physical layer (PHY) 840 is coupled to antenna 850 to interact with other wireless devices. PHY 840 may include circuitry to support the transmission and reception of radio frequency (RF) signals. For example, as shown in FIG. 8, PHY 840 includes power amplifier (PA) 842 and low noise amplifier (LNA) 844. Either or both of PA 842 and LNA 844 may include a parallel power amplifier such as those described above with reference to FIGS. 1 and 6. In some embodiments, PHY 840 includes additional functional blocks to perform filtering, frequency conversion or the like.

PHY 840 may be adapted to transmit/receive and modulate/demodulate signals of various formats and at various frequencies. For example, PHY 840 may be adapted to receive time domain multiple access (TDMA) signals, code domain multiple access (CDMA) signals, global system for mobile communications (GSM) signals, orthogonal frequency division multiplexing (OFDM) signals, multiple-input-multiple-output (MIMO) signals, spatial-division multiple access (SDMA) signals, or any other type of communications signals. The various embodiments of the present invention are not limited in this regard.

Example systems represented by FIG. 8 include cellular phones, personal digital assistants, wireless local area network interfaces, wireless wide area network stations and subscriber units, and the like. Many other systems uses for parallel power amplifiers exist. For example, PA 842 may be used in a desktop computer, a network bridge or router, or any other system without an antenna.

Media access control (MAC) layer 830 may be any suitable media access control layer implementation. For example, MAC 830 may be implemented in software, or hardware or any combination thereof. In some embodiments, a portion of MAC 830 may be implemented in hardware, and a portion may be implemented in software that is executed by processor 810. Further, MAC 830 may include a processor separate from processor 810.

Processor 810 may be any type of processor capable of communicating with memory 820, MAC 830, and other functional blocks (not shown). For example, processor 810 may be a microprocessor, digital signal processor (DSP), microcontroller, or the like.

Memory 820 represents an article that includes a machine readable medium. For example, memory 820 represents a random access memory (RAM), dynamic random access memory (DRAM), static random access memory (SRAM), read only memory (ROM), flash memory, or any other type of article that includes a medium readable by processor 810. Memory 820 may store instructions for performing software driven tasks. Memory 820 may also store data associated with the operation of system 800.

Although the various elements of system 800 are shown separate in FIG. 8, embodiments exist that combine the circuitry of processor 810, memory 820, MAC 830, and all or a portion of PHY 840 in a single integrated circuit. For example, MAC 830 and PA 842 may be combined together on an integrated circuit die. In some embodiments, the various elements of system 800 may be separately packaged and mounted on a common circuit board. In other embodiments, the various elements are separate integrated circuit dice packaged together, such as in a multi-chip module, and in still further embodiments, various elements are on the same integrated circuit die.

Amplifier circuits, bias circuits, and other embodiments of the present invention can be implemented in many ways. In some embodiments, they are implemented in integrated circuits as part of electronic systems. In some embodiments, design descriptions of the various embodiments of the present invention are included in libraries that enable designers to include them in custom or semi-custom designs. For example, any of the disclosed embodiments can be implemented in a synthesizable hardware design language, such as VHDL or Verilog, and distributed to designers for inclusion in standard cell designs, gate arrays, or the like. Likewise, any embodiment of the present invention can also be represented as a hard macro targeted to a specific manufacturing process. For example, portions of parallel power amplifier circuit 100 (FIG. 1) may be represented as polygons assigned to layers of an integrated circuit.

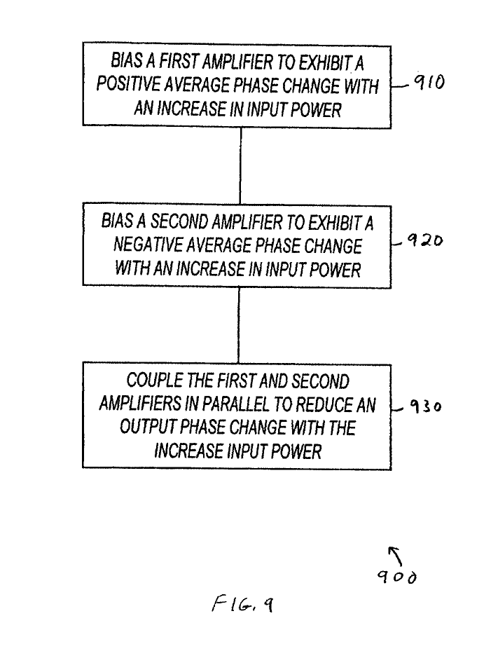

FIG. 9 shows a flowchart in accordance with various embodiments of the present invention. In some embodiments, method 900, or portions thereof, is performed by a parallel power amplifier circuit, embodiments of which are shown in previous figures. In other embodiments, method 900 is performed by an integrated circuit or an electronic system. Method 900 is not limited by the particular type of apparatus performing the method. The various actions in method 900 may be performed in the order presented, or may be performed in a different order. Further, in some embodiments, some actions listed in FIG. 9 are omitted from method 900.

Method 900 is shown beginning with block 910 in which a first amplifier is biased to exhibit a positive average phase change with an increase an input power. In some embodiments, this corresponds to biasing an amplifier at a point such as bias point 304 (FIG. 3) or bias point 706 (FIG. 7). The positive average phase change may have a characteristic similar to the change shown by curve 410 (FIG. 4).

At 920, a second amplifier is biased to exhibit a negative average phase change with an increase an input power. In some embodiments, this corresponds to biasing an amplifier at a point such as bias point 302 (FIG. 3) or bias point 702 (FIG. 7). The positive average phase change may have a characteristic similar to the change shown by curve 420 (FIG. 4).

At 930, the first and second amplifiers are coupled in parallel to reduce an output phase change with the increase in output power. This corresponds to parallel coupled amplifiers such as those shown in FIGS. 1 and 6. Further, in some embodiments, this corresponds to the act of combining output signals from various power amplifiers coupled in parallel.

Although the present invention has been described in conjunction with certain embodiments, it is to be understood that modifications and variations may be resorted to without departing from the spirit and scope of the invention as those skilled in the art readily understand. Such modifications and variations are considered to be within the scope of the invention and the appended claims.

What is claimed is:

1. A circuit comprising:
a first amplifier having a phase characteristic that varies in a first direction as input power increases;
a second amplifier having a phase characteristic that varies in a direction opposite the first direction as input power increases; and
a power combining circuit to combine output signals from the first and second amplifiers to provide a resultant signal with a reduced phase change with increasing input power.

2. The circuit of claim 1 further comprising a first bias circuit to bias the first amplifier.

3. The circuit of claim 2 further comprising a second bias circuit to bias the second amplifier.

4. The circuit of claim 3 wherein the first amplifier is biased to operate as a class A amplifier.

5. The circuit of claim 4 wherein the second amplifier is biased to operate as a class C amplifier.

6. The circuit of claim 1 further comprising a third amplifier coupled in parallel with the first and second amplifiers.

7. The circuit of claim 1 wherein the first and second amplifiers are separately biased.

8. The circuit of claim 7 further comprising a third separately biased amplifier coupled in parallel with the first and second amplifiers.

9. A power amplifier comprising a plurality of parallel coupled amplifiers, wherein at least one of the plurality of parallel coupled amplifiers exhibits a positive input capacitance change with increasing input power, and wherein at least one other of the plurality of parallel coupled amplifiers exhibits a negative input capacitance change with increasing input power.

10. The power amplifier of claim 9 wherein the at least one of the parallel coupled amplifiers includes a metal oxide semiconductor transistor, and the positive input capacitance change results from a gate-to-source capacitance change as a gate-to-source voltage changes.

11. The power amplifier of claim 9 wherein the at least one of the plurality of parallel coupled amplifiers is biased as a class A amplifier.

12. The power amplifier of claim 11 wherein the at least one other of the plurality of parallel coupled amplifiers is biased as a class C amplifier.

13. The power amplifier of claim 9 wherein the plurality of parallel coupled amplifiers includes at least three separately biased amplifiers.

14. A method comprising:
biasing a first amplifier to exhibit a positive average phase change with an increase in input power;
biasing a second amplifier to exhibit a negative average phase change with the increase in input power; and
coupling the first and second amplifiers in parallel to reduce an output phase change with the increase in input power.

15. The method of claim 14 wherein biasing the first amplifier comprises biasing the first amplifier as a class C amplifier.

16. The method of claim 14 wherein biasing the second amplifier comprises biasing the second amplifier as a class A amplifier.

17. The method of claim 14 further comprising:
biasing a third amplifier; and
coupling the third amplifier in parallel with the first and second amplifiers to increase output power.

18. A system comprising:
an omni-directional antenna; and
a power amplifier circuit coupled to drive a signal on the antenna, the power amplifier circuit comprising a plurality of parallel coupled amplifiers, wherein at least one of the plurality of parallel coupled amplifiers exhibits a positive input capacitance change with increasing input power, and wherein at least one other of the plurality of parallel coupled amplifiers exhibits a negative input capacitance change with increasing input power.

19. The system of claim 18 wherein the at least one of the parallel coupled amplifiers includes a metal oxide semiconductor transistor, and the positive input capacitance change results from a gate-to-source capacitance change as a gate-to-source voltage changes.

20. The system of claim 18 wherein the plurality of parallel coupled amplifiers includes at least three separately biased amplifiers.
